(19) United States
(12) Patent Application Publication
(10) Pub. No.: US 2018/0254203 A1
(43) Pub. Date: Sep. 6, 2018

(54) APPARATUS AND METHOD TO REDUCE PARTICLE FORMATION ON SUBSTRATES IN POST SELECTIVE ETCH PROCESS

(71) Applicant: Applied Materials, Inc., Santa Clara, CA (US)

(72) Inventors: Saravjeet SINGH, Santa Clara, CA (US); Alan TSO, San Jose, CA (US); Tae Won KIM, Dublin, CA (US)

(21) Appl. No.: 15/448,090

(22) Filed: Mar. 2, 2017

(51) Int. Cl. H01L 21/67

(52) U.S. Cl. CPC H01L 21/67103; H01L 21/67201

(57) ABSTRACT

The present disclosure generally relates to apparatuses and methods for reducing particle contamination on substrate surfaces. In one example, the apparatus is embodied as a load lock chamber including a top heater liner disposed over and coupled to a heater pedestal. The top heater liner generally includes a top plate and one or more walls, which support the top heater liner over the heater pedestal. Since the top heater liner is in contact with the heater pedestal, the top heater liner is generally heated to a temperature at which contaminating particles are volatile, such as greater than about 100° C. In operation, volatile fluorine passing through or adjacent to the hot top heater liner remains in gaseous form and thus are pumped out of the load lock chamber. The top heater liner thus advantageously reduces the potential for contaminating particles depositing on the substrate surface and improves overall production yield.

### BACKGROUND

### Field

Examples of the present disclosure generally relate to apparatuses and methods for reducing particle formation on substrates in a semiconductor substrate processing system.

### Description of the Related Art

Electronic devices, such as flat panel displays and integrated circuits, are commonly fabricated by a series of processes in which layers are deposited on a surface of a substrate and the deposited material is etched into desired patterns. The processes commonly include physical vapor deposition (PVD), chemical vapor deposition (CVD), plasma enhanced CVD (PECVD), and other plasma processing methods.

One problem encountered during the various stages of processing is the concentration of contaminating particles, such as fluorine byproducts, on the substrate surface. When the substrate is heated on a heater pedestal in the load lock chamber after processing these contaminating particles generally volatize to a gas and then solidify and accumulate on the colder ceiling or sidewalls of the load lock chamber. Further heating generally causes the accumulated particles to crack, flake off of the ceiling or sidewalls of the load lock chamber, and fall back onto the substrate surface. These surface contaminating particles are detrimental to device functionality. Heating the load lock chamber in its entirety, including the colder ceiling or sidewalls, to reduce particle contamination would be inefficient and would diminish the functionality of various chamber components, which may be inoperable at higher temperatures.

Therefore, there is a need in the art for improved apparatuses and methods that effectively reduce the generation of contaminating particles on the substrate surface after etch processes.

### SUMMARY

The present disclosure generally relates to apparatuses and methods for reducing particle contamination on substrate surfaces using a top heater liner over a heater pedestal in a load lock chamber of a semiconductor substrate processing system. In one example the apparatus is a load lock chamber. The load lock chamber includes a chamber body having chamber walls and a chamber lid. Inner surfaces of the chamber walls and a bottom surface of the chamber lid define an internal volume. A heater pedestal is disposed in the internal volume. A top heater liner is disposed in contact with the heater pedestal. The top heater liner includes a top plate. At least one wall is disposed in contact with the top plate and the heater pedestal and spaces the top plate above the heater pedestal. The at least one wall has two substrate transfer openings disposed 180 degrees apart.

In another example the apparatus is a load lock chamber. The load lock chamber includes a chamber body having chamber walls and a chamber lid. Inner surfaces of the chamber walls and a bottom surface of the chamber lid define an internal volume. A heater pedestal is disposed in the internal volume. A top heater liner is disposed in contact with the heater pedestal. The top heater liner includes a top plate, at least two walls disposed in contact with the top plate and the heater pedestal and spacing the top plate above the heater pedestal, two substrate transfer openings defined between the at least two walls and below the top plate, the substrate transfer openings disposed 180 degrees apart.

In yet another example, the apparatus is a top heater liner. The top heater liner includes a cylindrical top plate and a cylindrical top plate and at least one wall disposed in contact with the top plate. The at least one wall has two substrate transfer openings disposed 180 degrees apart.

### BRIEF DESCRIPTION OF THE DRAWINGS

So that the manner in which the above recited features of the present disclosure can be understood in detail, a more particular description of the disclosure, briefly summarized above, may be had by reference to examples, some of which are illustrated in the appended drawings. It is to be noted, however, that the appended drawings illustrate only exemplary examples and are therefore not to be considered limiting of its scope, may admit to other equally effective examples.

FIG. 1 is a schematic top view of an exemplary substrate processing system according to examples described herein.

FIG. 2 is a cross-sectional view of a load lock chamber of FIG. 1 according to examples described herein.

FIG. 3 is a perspective view of a top heater liner of the load lock chamber of FIG. 2 according to one example described herein.

FIG. 4 is a schematic view of a load lock chamber having the top heater liner of FIG. 3.

FIG. 5 is a perspective view of an alternative top heater liner of the load lock chamber of FIG. 2 according to another example described herein.

FIG. 6 is a cross-sectional view of a load lock chamber having the top heater liner of FIG. 5.

To facilitate understanding, identical reference numerals have been used, where possible, to designate identical elements that are common to the figures. It is contemplated that elements and features of one example may be beneficially incorporated in other examples without further recitation.

### DETAILED DESCRIPTION

The present disclosure generally relates to apparatuses and methods for reducing particle contamination on substrate surfaces in a semiconductor substrate processing system. In one example, the apparatus is embodied as a load lock chamber. The load lock chamber includes a top heater liner disposed over and coupled to a heater pedestal. The top heater liner generally includes a perforated or solid top plate and one or more walls, which support the top heater liner over the heater pedestal. Since the top heater liner is in contact with the heater pedestal, the top heater liner is generally heated to a temperature at which substrate surface contaminating particles are volatile, such as greater than about 100 degrees Celsius (° C.). In operation, volatile fluorine passing through or adjacent to the hot top heater liner remains in gaseous form and thus are pumped out of the load lock chamber. The top heater liner thus advantageously assists in reducing the potential for contaminating particles depositing on the substrate surface and, thus, improves overall production yield.

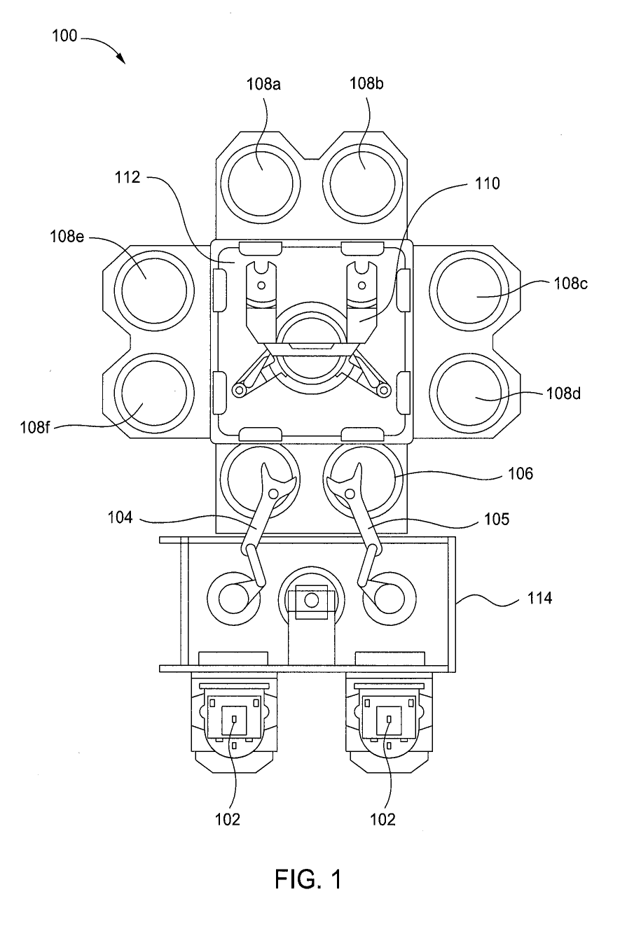

FIG. 1 is a schematic top view of an exemplary substrate processing system 100 according to examples described herein. The exemplary substrate processing system 100 includes a plurality of processing chambers 108a-f, a transfer chamber 112, a load lock chamber 105, and a factory interface 114. The transfer chamber 112 is coupled to the load lock chamber 105 and the processing chambers 108a-f. The load lock chamber 105 is coupled between the factory interface 114 and the transfer chamber 112.

The factory interface 114 is maintained at a substantially atmospheric pressure and includes one or more robots 104 for transferring substrates between cassettes 102 coupled to the factory interface 114 and the load lock chamber 105. The load lock chamber 105 is operational to receive the substrates at atmospheric pressure from the factory interface 114 and then pump down the interior volume of the load lock chamber 105 to a low pressure (i.e., vacuum), upon which the substrates are generally then transferred from the load lock chamber 105 into the transfer chamber 112 by a second robotic arm 110 disposed in the transfer chamber 112.

The second robotic arm 110 is configured to transfer substrates into the substrate processing chambers 108a-f for processing. Each substrate processing chamber 108a-f can be outfitted to perform a substrate processing operation such as dry etch processes, cyclical layer deposition (CLD), atomic layer deposition (ALD), chemical vapor deposition (CVD), physical vapor deposition (PVD), pre-clean, substrate degas, substrate orientation, and other substrate processes. At least one of the substrate processing chambers 108a-f is configured to perform a process that uses a halogen containing gas. For example, at least one of the substrate processing chambers 108a-f is configured etch the substrate using fluorine or a fluorine containing gas. After processing in one or more of the substrate processing chambers 108a-f, the substrates are transferred back to the load lock chamber 105 by the second robotic arm 110, and ultimately back through the factory interface 114 to the cassettes 102.

At least one of the substrate processing chambers 108a-f is illustratively described as a processing chamber for etching silicon; however, the disclosure also applies to processing chambers configured for performing other processes. As discussed above, one problem encountered during the various stages of processing is the concentration of contaminating particles on the substrate surface. For example, silicon fluoride (SiF) is a common byproduct of silicon etching, and is volatile at temperatures greater than about 100 degrees Celsius. Throughout processing, SiF surface contaminating particles, or etch residue, accumulate on the substrate surface. When the processed substrate is vented to atmosphere in the load lock chamber 105, at least some of these surface contaminating particles generally remain on the substrate surface. When the substrate is heated in the pair of load lock chamber 105, the surface contaminating particles generally volatize, however, when the volatized byproducts including fluorine from the SiF contact the colder lid or sidewalls of the load lock chamber 105, the fluorine reacts with the metals on those surfaces and generally forms a film that is susceptible to crack, flake off, and fall back onto the substrate surface as a contaminant. As discussed below, the pair of load lock chamber 105 are configured to substantially reduce the potential for the generation of films on the surfaces of the load lock chamber 105 that could potentially become contaminating particles on the substrate surface.

The load lock chamber 105 is illustratively shown as a single substrate supporting load lock chamber; however, the disclosure also applies to load lock chambers configured to support two or more substrates. For example, the disclosure also applies to a stacked load lock chamber having a lower slot and an upper slot, the lower slot configured to support a first substrate and the upper slot configured to support a second substrate. Additionally, the load lock chamber 105 is illustratively shown as a load lock chamber configured to support a circular substrate, such as a 300 millimeter (mm) substrate; however, the disclosure also applies to substrates of any shape and any dimension and load lock chambers configured for support thereof.

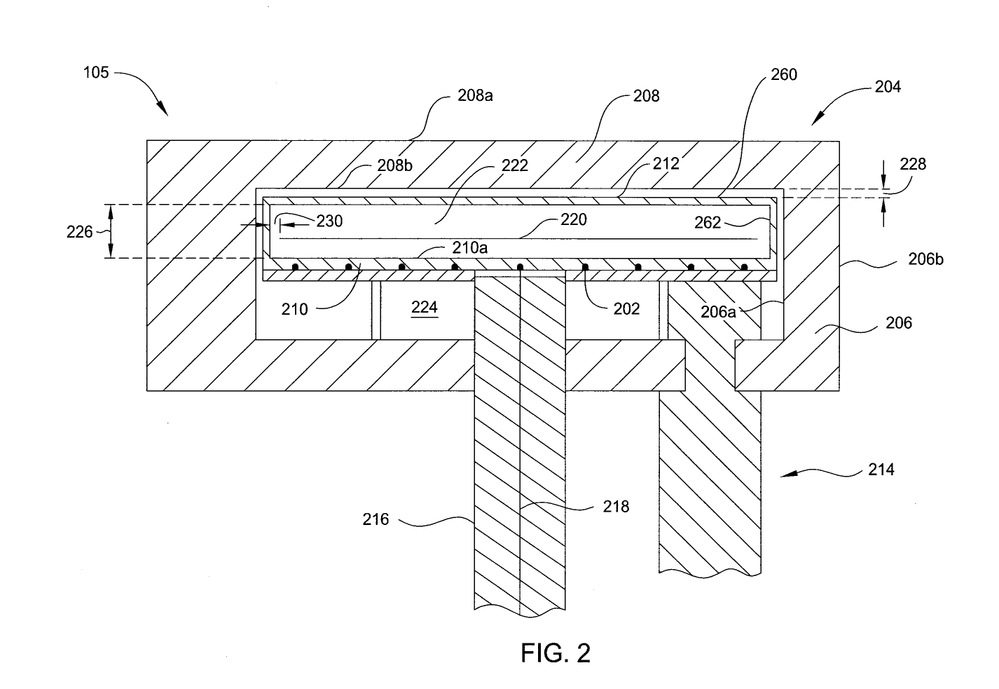

FIG. 2 is a cross-sectional view of a load lock chamber 105 of FIG. 1 according to examples described herein. The load lock chamber 105 generally includes a chamber body 204 defined by chamber walls 206 and a chamber lid 208. Each of the chamber walls 206 has an inner surface 206a and an outer surface 206b . The inner surfaces 206a are exposed to the inside of the chamber body 204 and the outer surfaces 206b are exposed to the atmosphere, i.e., the environment outside of the chamber body 204. The chamber walls 206 include two slit valve openings 222 formed therethrough, one of which is shown in FIG. 2. The slit valve openings 222 selectively connect the chamber body 204 to the factory interface 114 and the transfer chamber 112. The chamber lid 208 has an upper surface 208a and a bottom surface 208b . An internal volume 224 is defined by the inner surfaces 206a of the chamber walls 206 and the bottom surface 208b of the chamber lid 208. A vacuum pump 214 is coupled to the internal volume 224 of the load lock chamber 105 to control the pressure therein between vacuum and atmospheric states.

A heater pedestal 210 and a top heater liner 212 are disposed in the internal volume 224. The heater pedestal 210 is coupled to a support shaft 216 that extends through the chamber body 204. A resistive heating element 202 is disposed in the heater pedestal 210 and is coupled to a power source (not shown) by a cable 218 that extends through the support shaft 216. The heating element 202 may alternatively be suitable heating element(s) other than resistive heaters.

The top heater liner 212 generally includes a top plate 260 and one or more walls 262. The top plate 260 is spaced a distance 226 from the upper surface 210a of the heater pedestal 210. The distance 226 is generally between about 1000 mils and about 2000 mils, for example, about 1300 mils. The top plate 260 is spaced a distance 228 from the bottom surface 208b of the chamber lid 208. The distance 228 is generally between about 50 mils and about 200 mils, for example, about 100 mils.

FIG. 2 illustratively shows a substrate 220 disposed within the load lock chamber 105. The heater pedestal 210 is generally sized to accommodate the substrate 220 between the walls 262 of the top heater liner 212. As shown in FIG. 2, the diameter of the heater pedestal 210 and top heater liner 212 are generally substantially equal. The diameter of the heater pedestal 210 and the diameter of the top heater liner 212 are greater than the diameter of the substrate 220. For example, a distance 230 between an edge of the substrate 220 and the edge of the heater pedestal 210 is generally between about 200 and about 500 mils, such as about 470 mils. These illustrative distances are for examples using a 300 mm substrate; however, the load lock chamber 105 and components thereof may be configured to accommodate substrates of other shapes and sizes.

The top heater liner 212 is manufactured from a material having high thermal conductivity, such as a metal, for example aluminum. The walls 262 couple the top heater liner 212 and the heater pedestal 210 and conduct heat from the heater pedestal 210 to the top heater liner 212. This coupling provides for a more robust contact between the top heater liner 212 and the heater pedestal 210. The robust contact between the top heater liner 212 and the heater pedestal 210 increases the heat transfer from the heater pedestal 210 to the perforated top plate 260.

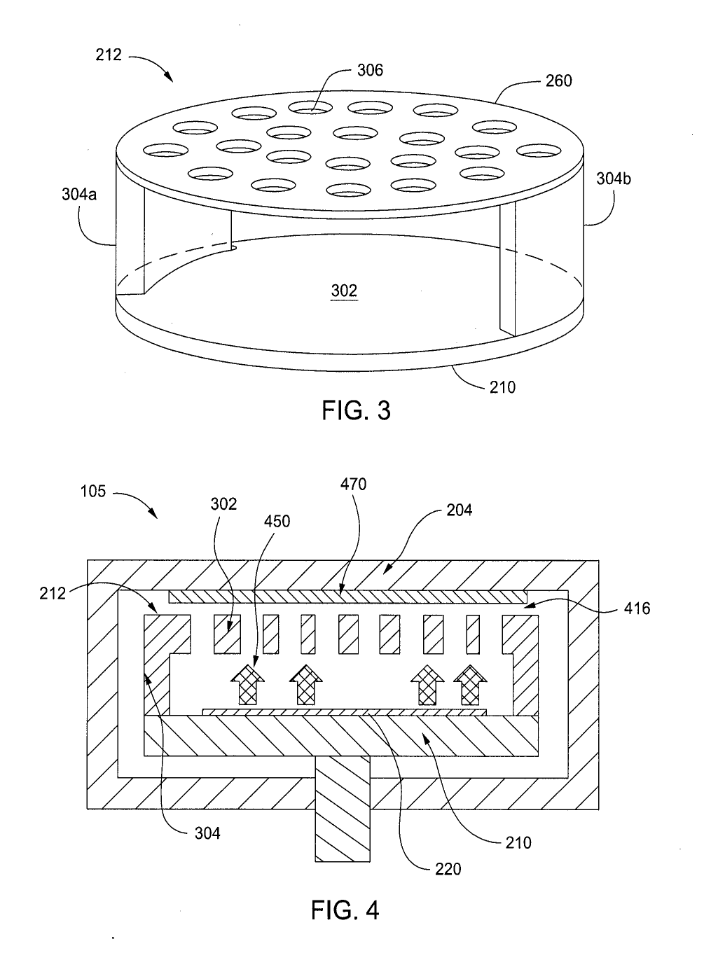

FIG. 3 is a perspective view of a top heater liner 212 of the load lock chamber 105 of FIG. 2 disposed in contact with the heater pedestal 210 according to one example described herein. The top plate 260 of the top heater liner 212 is generally perforated or solid. In the example depicted in FIG. 3, the top plate 260 generally includes a plurality of openings 306 that allow gas to pass through. The top plate 260 has a plurality of walls 262, shown in FIG. 3 as a first wall 304a and second wall 304b , which extend from the bottom surface 260a of the top plate 260. The walls 304 couple the top plate 260 to the heater pedestal 210. The one or more walls 304 generally couple the top plate 260 to the heater pedestal 210 through fasteners or other fastening mechanisms. In one example, the heater pedestal 210 includes one or more notches or recesses formed in the surface thereof, which are configured to align with and couple to the one or more walls 304. In another example, the one or more walls 304 further include fastening brackets which couple to the heater pedestal 210 with fasteners, such as screws, bolts, or pins. In yet another example, the top heater liner 212 and the heater pedestal 210 may be manufactured from a single block of metal such that they are single unit including various components. The coupling between the top heater liner 212 and the heater pedestal 210 through the walls 304 provides for a more robust contact between the top heater liner 212 and the heater pedestal 210. The robust contact between the top heater liner 212 and the heater pedestal 210 increases the heat transfer from the heater pedestal 210 to the perforated top plate 260.

As shown in FIG. 3, the top plate 260 is cylindrical, and the first wall 304a is spaced 180 degrees apart from the second wall 304b . The first wall 304a and the second wall 304b are curved such that the outer surfaces of the walls 304 are flush with the circumference of the outer edge of the heater pedestal 210. The first wall 304a and the second wall 304b create a two substrate transfers opening 302 between the heater pedestal 210 and the top plate 260. The substrate transfer openings 302 are 180 degrees apart such that the two substrate transfer openings 302 aligns with the two slit valve openings 222 to facilitate transfer of the substrate 220 into and out opposite sides of the load lock chamber 105.

The height of the substrate transfer opening 302 is great enough to allow a robot, such as the second robotic arm 110, and the substrate 220 to pass therethrough. Because the first wall 304a and the second wall 304b are spaced apart, the substrate transfer opening 302 is also wide enough to accommodate the substrate 220 passing therethrough. In an example using a 300 mm substrate, the substrate transfer opening 302 is generally wider than 350 mm. In an example using a 450 mm substrate, the space 302 is generally wider than 500 mm. In an example using a 200 mm substrate, the substrate transfer opening 302 is generally wider than 250 mm. While the example shown in FIG. 3 is depicted as a first wall 304a and a second wall 304b spaced apart 180° with the height of the substrate transfer opening 302 extending from the heater pedestal 210 to the top plate 260, the top heater liner 212 may include a single wall 304 having two substrate transfer openings 302 therein, the height of each of the substrate transfer openings 302 being less than the height between the heater pedestal 210 and the top plate 260, but still great enough to accommodate a robot with the substrate 220 passing therethrough, and the width of the substrate transfer openings 302 being wide enough to accommodate the substrate 220 passing therethrough.

The open area of the top plate 260, or size and density of the openings 306, is generally selected to efficiently facilitate volitzation of etch residue on the substrate surface or the colder chamber walls and lids and allow the volatized material 450 to pass therethrough. In other words, the open area is selected to facilitate volitzation of etch residue into a gaseous, volatized material 450. The open area of the top plate 260 is generally selected in response to the expected size of the particles of the etch residue such that it provides a physical barrier to flakes from the etch residue.

As discussed above, etch residue generally accumulates on the surface of the substrate 220 during the various stages of processing. When the substrate 220 enters the load lock chamber 105 after undergoing various processes, such as silicon etching, etchant SiF byproducts have generally accumulated on the surface of the substrate 220. In the load lock chamber 105, the substrate 220 is heated on the heater pedestal 210. The heater pedestal 210 is generally heated to a temperature between about 200° C. and about 350° C., whereas the chamber body is generally at a temperature between about 65° C. and about 90° C. In comparison, the top plate 260 is generally heated to a temperature greater than about 100° C., or a temperature at which the etch residue becomes volatile, due to the conductivity of the walls 304.

As shown in FIG. 4, when the substrate 220 is heated on the heater pedestal 210, the etch residue 470 present on the substrate is volatized and travels up into contact with the cooler surfaces of the chamber body 204, generally on the bottom surface 208b of the chamber lid 208, as shown by arrows of volatized material 450. The etch residue condenses with the chamber body 240 and forms a film of etch residue 470. Due to heating and cooling of the chamber lid 208, the accumulated film of etch residue 470 generally cracks and flakes off. In conventional systems, the flakes from the film of etch residue 470 generally fall and deposit on the surface of the substrate 220. However, the presence of the top heater liner 212 re-volatizes the flakes and substantially reduces or eliminates the flakes from reaching and contaminating the surface of the substrate 220. More specifically, when the heater pedestal 210 is heated to between about 200° C. and about 350° C., the one or more walls 304, which are manufactured from a conductive material such as aluminum, conduct heat generated at the heater pedestal 210 through the walls 304 and to the top plate 260 such that the temperature of the perforated top plate 260 is between about 150° C. and about 350° C. Because the top heater liner 212 is at a temperature between about 150° C. and about 350° C., etch residue which volatizes and passes through or adjacent to the top plate 260 remains volatized and does not accumulate on the surface of the substrate 220. In other words, the top heater liner 212 allows volatized material 450, from the etch residue which had accumulated on the surface of the substrate 220 to travel up towards the chamber body 204. The top heater liner 212 also prevents material from the film of etch residue 470 that flakes off of the chamber body 204 from falling back onto the surface of the substrate 220. Therefore, the top heater liner 212 traps the volatized material 450 in the trap area 416 defined between the chamber body 204 and the top heater liner 212. The volatized material 450 is generally then be pumped out of the load lock chamber 105 through an outlet by the vacuum pump (shown in FIG. 2).

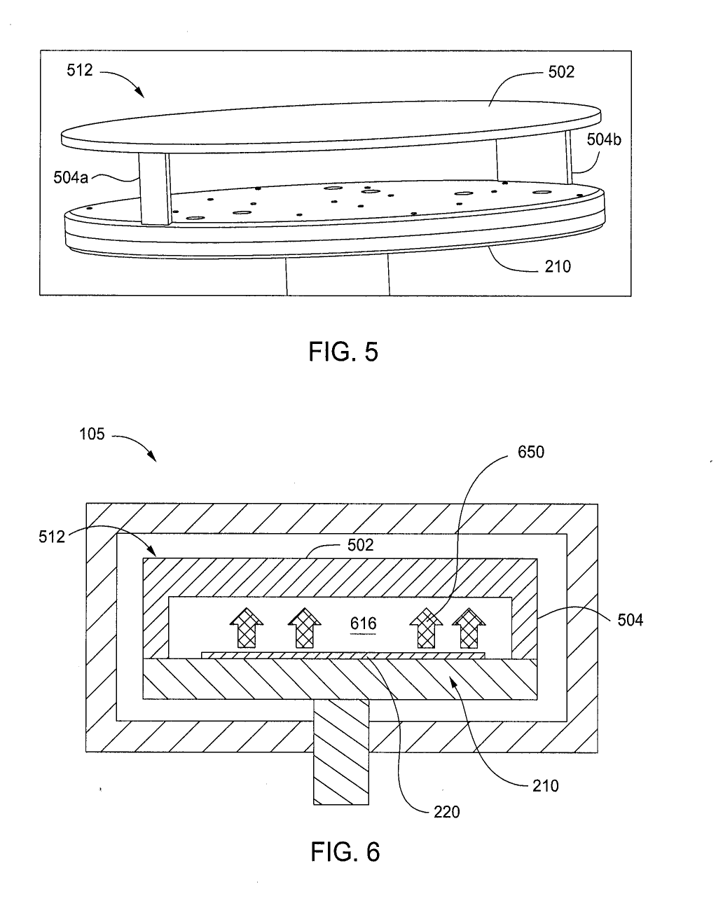

FIG. 5 is a perspective view of another embodiment of a top heater liner 512 that may be utilized with the load lock chamber 105 of FIG. 2. The top heater liner 512 is similar to the top heater liner 212; however, the top heater liner 512 generally includes a solid top plate 502 and one or more walls 504 (a first wall 504a and second wall 504b are illustratively shown). The one or more walls 504 couple the solid top plate 502 to the heater pedestal 210. The one or more walls 504 generally couple the solid top plate 502 to the heater pedestal 210 through fasteners or other fastening mechanisms. In one example, the heater pedestal 210 includes one or more notches or recesses formed in the surface thereof, which are configured to align with and couple to the one or more walls 504. In another example, the one or more walls 504 further include fastening brackets which couple to the heater pedestal 210 with fasteners, such as screws, bolts, or pins. In yet another example, the top heater liner 512 and the heater pedestal 210 is manufactured from a single block of metal such that they are single unit including various components.

As shown in FIG. 5, the solid top plate 502 is cylindrical, and the first wall 504a is spaced 180 degrees apart from the second wall 504b . The first wall 504a and the second wall 504b are curved such that the outer surfaces of the walls 504 are flush with the circumference of the outer edge of the heater pedestal 210.

The diameter of the top heater liner 512 is generally selected as described above with reference to the top heater liner 212.

Etch residue generally accumulates on the surface of the substrate 220 during the various stages of processing. When the substrate 220 enters the load lock chamber 105 after undergoing various processes, such as silicon etching, etchant SiF byproducts have generally accumulated on the surface of the substrate 220. In the load lock chamber 105, the substrate 220 is heated on the heater pedestal 210. The heater pedestal 210 is generally heated to a temperature between about 200° C. and about 350° C., whereas the chamber body is generally at a temperature between about 65° C. and about 90° C.

As shown in FIG. 6, when the substrate 220 is heated on the heater pedestal 210, the etch residue is volatized and forms a volatized material 450 which travels up towards the solid top plate 502. In operation, the top heater liner 512 traps the volatized material 650 in the space between the heater pedestal 210 and the solid top plate 502 and forces the volatized material 450 to travel laterally between the substrate surface and the solid top plate 502. More specifically, when the heater pedestal 210 is heated to between about 200° C. and about 350° C., the one or more walls 504, which are manufactured from a conductive material such as aluminum, conduct heat generated at the heater pedestal 210 through the walls 504 and to the solid top plate 502 such that the temperature of the solid top plate 502 is between about 150° C. and about 350° C. Because the top heater liner 512 is at a temperature between about 150° C. and about 350° C., volatized material 450 which travels from the surface of the substrate 220 towards the solid top plate 502 remains volatized. In other words, the top heater liner 512 allows volatized material 450, which had accumulated on the surface of the substrate 220 to travel up towards the solid top plate 502, the heat of which radiates to keep the volatized material 450 in a volatized, gaseous form and traps the volatized material 450 in a trap region 616. The volatized material 450 is generally then pumped out of the load lock chamber 105 through an outlet such as a vacuum pump (shown in FIG. 2).

Benefits of the apparatuses and methods described herein include further reduction or elimination of particle contamination on the surface of a substrate in a load lock chamber after the substrate has been processed. This reduction or elimination of substrate surface particle contamination results in increased throughput, uniformity, and overall semiconductor substrate functionality.

While the foregoing is directed to examples of the present disclosure, other and further examples of the disclosure may be devised without departing from the basic scope thereof, and the scope thereof is determined by the claims that follow.

What is claimed is:

1. A load lock chamber comprising:
a chamber body having chamber walls and a chamber lid, inner surfaces of the chamber walls and a bottom surface of the chamber lid defining an internal volume;
a heater pedestal disposed in the internal volume; and
a top heater liner disposed in contact with the heater pedestal, the top heater liner comprising:
a top plate; and
at least one wall disposed in contact with the top plate and the heater pedestal and spacing the top plate above the heater pedestal, the at least one wall having two substrate transfer openings disposed 180 degrees apart.

2. The load lock chamber of claim 1, wherein a distance between the bottom surface of the chamber lid and the top plate is between about 50 mils and about 200 mils.

3. The load lock chamber of claim 2, wherein the distance between the bottom surface of the chamber lid and the top plate is about 100 mils.

4. The load lock chamber of claim 1, wherein a distance between the heater pedestal and the top plate is between about 1,000 mils and about 2,000 mils.

5. The load lock chamber of claim 4, wherein the distance between the heater pedestal and the top plate is about 1,300 mils.

6. The load lock chamber of claim 1, wherein the top plate comprises a plurality of openings sized to allow volatized material to pass therethrough, but to prevent solidified contaminating particles from passing therethrough.

7. The load lock chamber of claim 1, wherein the heater pedestal and the top plate are of equal size.

8. The load lock chamber of claim 1, wherein the top heater liner comprises at least a first wall and a second wall spaced 180 degrees apart.

9. The load lock chamber of claim 1, wherein the top plate is perforated.

10. A load lock chamber comprising:
a chamber body having chamber walls and a chamber lid, inner surfaces of the chamber walls and a bottom surface of the chamber lid defining an internal volume;
a heater pedestal disposed in the internal volume; and
a top heater liner disposed in contact with the heater pedestal, the top heater liner comprising:
a top plate;
at least two walls disposed in contact with the top plate and the heater pedestal and spacing the top plate above the heater pedestal; and
two substrate transfer openings defined between the at least two walls and below the top plate, the substrate transfer openings disposed 180 degrees apart.

11. The load lock chamber of claim 10, wherein a distance between the bottom surface of the chamber lid and the top plate is between about 50 mils and about 200 mils.

12. The load lock chamber of claim 11, wherein the distance between the bottom surface of the chamber lid and the top plate is about 100 mils.

13. The load lock chamber of claim 10, wherein a distance between the heater pedestal and the top plate is between about 1,000 mils and about 2,000 mils.

14. The load lock chamber of claim 10, wherein the distance between the heater pedestal and the top plate is about 1,300 mils.

15. The load lock chamber of claim 10, wherein the heater pedestal and the top plate are about equal in diameter.

16. The load lock chamber of claim 10, wherein the top plate is perforated.

17. The load lock chamber of claim 16, wherein the top plate is solid.

18. A top heater liner assembly comprising:
a cylindrical top plate; and
at least one wall disposed extending from the top plate, the at least one wall having two substrate transfer openings disposed about 180 degrees apart.

19. The top heater liner assembly of claim 18, wherein the top plate is solid, and wherein the top plate and the at least one wall are manufactured from conductive material.

20. The top heater liner assembly of claim 18, wherein the top plate is perforated and comprises a plurality of openings formed therethrough.
